(19) United States
(12) Patent Application Publication
(10) Pub. No.: US 2024/0321983 A1
(43) Pub. Date: Sep. 26, 2024

(54) INTEGRATED CIRCUIT DEVICES

(71) Applicant: Samsung Electronics Co., Ltd., Suwon-si (KR)

(72) Inventor: Jongryeol Yoo, Suwon-si (KR)

(21) Appl. No.: 18/609,186

(22) Filed: Mar. 19, 2024

(30) Foreign Application Priority Data
Mar. 24, 2023 (KR) 10-2023-0039034
Apr. 18, 2023 (KR) 10-2023-0050901

(51) Int. Cl. H01L 29/417; H01L 27/088; H01L 29/06; H01L 29/423; H01L 29/775; H01L 29/786

(52) U.S. Cl. CPC H01L 29/41775; H01L 27/088; H01L 29/0673; H01L 29/42376; H01L 29/42392; H01L 29/775; H01L 29/78696

(57) ABSTRACT

An integrated circuit device may include a fin-type active region that protrudes from a substrate and extends in a first direction, a plurality of semiconductor patterns on the fin-type active region and separated from each other in a vertical direction, a gate line on the fin-type active region, the gate line surrounding the semiconductor patterns and extending in a second direction that intersects the first direction, a source/drain region on the fin-type active region, adjacent to the gate line and connected to the semiconductor patterns, wherein the source/drain region includes a first semiconductor layer contacting the semiconductor patterns and including a semiconductor material including a first element including at least one selected from the group consisting of fluorine, oxygen, argon, and nitrogen, and an inner spacer between the source/drain region and the gate line and including an oxide including the first element or a nitride including the first element.

### CROSS-REFERENCE TO RELATED APPLICATIONS

This application is based on and claims priority under 35 U.S.C. § 119 to Korean Patent Application Nos. 10-2023-0039034, filed on Mar. 24, 2023, and to 10-2023-0050901, filed on Apr. 18, 2023, in the Korean Intellectual Property Office, and the entire contents of the above-identified applications are incorporated by reference herein.

### TECHNICAL FIELD

The present disclosure relates to integrated circuit devices, and more particularly, to integrated circuit devices including field-effect transistors (FET).

### BACKGROUND

With the development of electronic technologies, there has been increasing demand for greater integration of integrated circuit devices, and down-scaling of integrated circuit devices is in progress. With the down-scaling of integrated circuit devices, a short channel effect of transistors therein may occur, thereby decreasing the reliability of integrated circuit devices. To reduce the short channel effect, integrated circuit devices having multi-gate structures, such as nanosheet-type transistors, have been proposed.

### SUMMARY

The present disclosure provides integrated circuit devices in which failures are prevented or reduced in a process of removing a sacrificial gate electrode.

According to some aspects of the inventive concepts, there is provided an integrated circuit device including a fin-type active region that protrudes from a substrate and extends in a first horizontal direction, a plurality of semiconductor patterns on the fin-type active region and separated from each other in a vertical direction, a gate line on the fin-type active region, the gate line surrounding the plurality of semiconductor patterns and extending in a second horizontal direction that intersects the first horizontal direction, a source/drain region on the fin-type active region, adjacent to the gate line and connected to the plurality of semiconductor patterns, in which the source/drain region includes a first semiconductor layer that contacts the plurality of semiconductor patterns, and in which the first semiconductor layer includes a semiconductor material including a first element including at least one selected from the group consisting of fluorine, oxygen, argon, and nitrogen, and an inner spacer between the source/drain region and the gate line, the inner spacer including an oxide including the first element or a nitride including the first element.

According to some aspects of the inventive concepts, there is provided an integrated circuit device including a fin-type active region that protrudes from a substrate and extends in a first horizontal direction, a plurality of semiconductor patterns on the fin-type active region and overlapping with each other in a vertical direction, a gate line on the fin-type active region, the gate line surrounding the plurality of semiconductor patterns and extending in a second horizontal direction that intersects the first horizontal direction, a source/drain region on the fin-type active region, adjacent to the gate line and connected to the plurality of semiconductor patterns, and an inner spacer between the source/drain region and the gate line, wherein the source/drain region includes a first semiconductor layer having an outer sidewall and an inner sidewall, wherein the outer sidewall is in contact with the plurality of semiconductor patterns and the inner spacer, and the inner sidewall is opposite to the outer sidewall, and a second semiconductor layer on the inner sidewall of the first semiconductor layer, and wherein the first semiconductor layer includes a semiconductor material including a first element including at least one selected from the group consisting of fluorine, oxygen, argon, and nitrogen, and the inner spacer includes an oxide including the first element or a nitride including the first element.

According to some aspects of the inventive concepts, there is provided an integrated circuit device including a fin-type active region that protrudes from a substrate and extends in a first horizontal direction, a plurality of semiconductor patterns on the fin-type active region and overlapping with each other in a vertical direction, a gate line on the fin-type active region, the gate line surrounding the plurality of semiconductor patterns and extending in a second horizontal direction that intersects the first horizontal direction, a source/drain region on the fin-type active region, the source/drain region being adjacent to the gate line and connected to the plurality of semiconductor patterns, an inner spacer between the source/drain region and the gate line, and a gate insulating layer between the gate line and the plurality of semiconductor patterns and between the gate line and the inner spacer, wherein the source/drain region includes a buffer layer having an outer sidewall and an inner sidewall, the outer sidewall in contact with the plurality of semiconductor patterns and the inner spacer, and the inner sidewall opposite to the outer sidewall, and a main semiconductor layer on the inner sidewall of the buffer layer, the buffer layer including a semiconductor material including a first element including at least one selected from the group consisting of fluorine, oxygen, argon, and nitrogen, and the outer sidewall of the buffer layer includes a plurality of grooves, the plurality of grooves being separated from each other in the vertical direction at locations corresponding to the inner spacer.

### BRIEF DESCRIPTION OF THE DRAWINGS

Embodiments will be more clearly understood from the following detailed description taken in conjunction with the accompanying drawings in which:

FIG. 1 is a schematic layout diagram of an integrated circuit device according to some embodiments;

FIG. 2 is a cross-sectional view taken along line A1-A1′ in FIG. 1;

FIG. 3 is a cross-sectional view taken along line A2-A2′ in FIG. 1;

FIG. 4 is an enlarged view of a region CX1 in FIG. 2;

FIG. 5 is a cross-sectional view of an integrated circuit device according to some embodiments;

FIG. 6 is an enlarged view of a region CX1 in FIG. 5;

FIG. 7 is a cross-sectional view of an integrated circuit device according to some embodiments;

FIG. 8 is an enlarged view of a region CX1 in FIG. 7;

FIGS. 9, 10A, 10B, 11, 12, 13, 14A, 14B, 15, 16A, and 16B are cross-sectional views of stages in a method of manufacturing an integrated circuit device, according to some embodiments, wherein FIGS. 9, 10A, 11, 12, 13, 14A, 15, and 16A are cross-sectional views corresponding to the cross-section taken along line A1-A1′ in FIG. 1 and FIGS. 10B, 14B, and 16B are cross-sectional views corresponding to the cross-section taken along line A2-A2′ in FIG. 1; and

FIGS. 17, 18, 19, 20, and 21 are cross-sectional views of stages in a method of manufacturing an integrated circuit device, according to some embodiments.

### DETAILED DESCRIPTION

Hereinafter, some examples of embodiments of the inventive concept are described in detail with reference to the accompanying drawings.

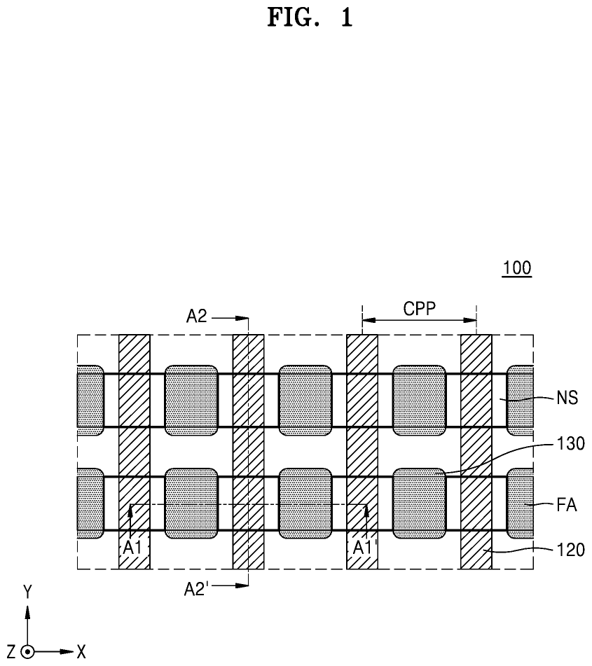

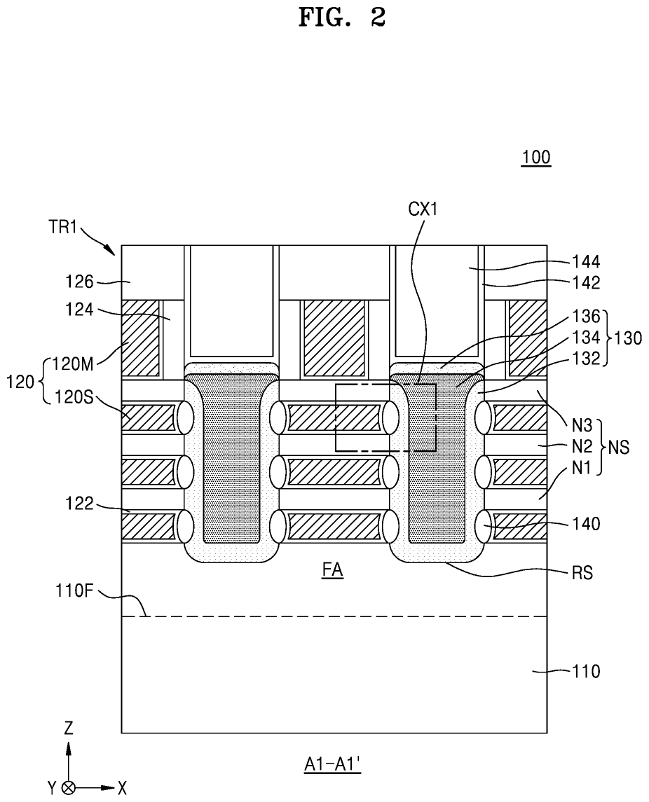

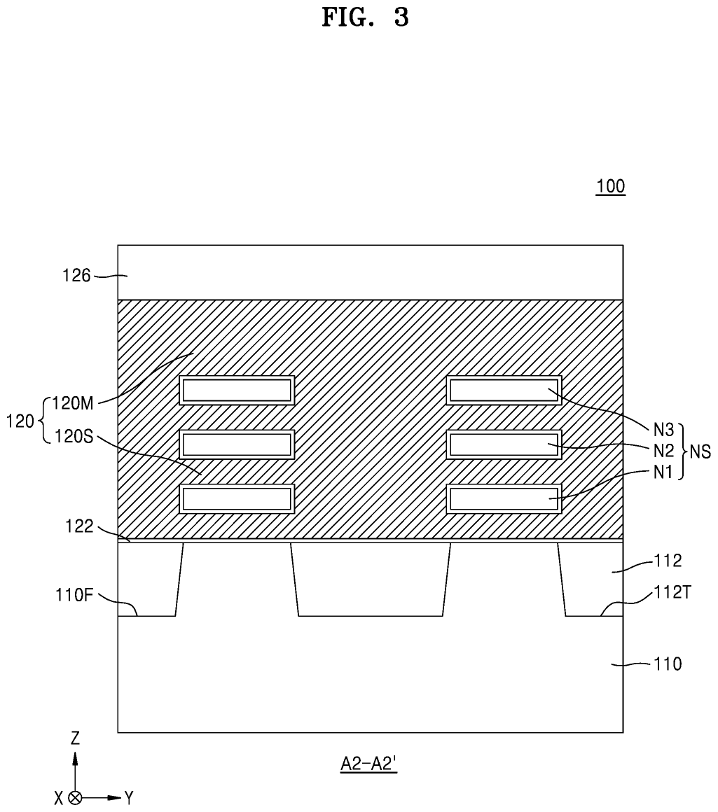

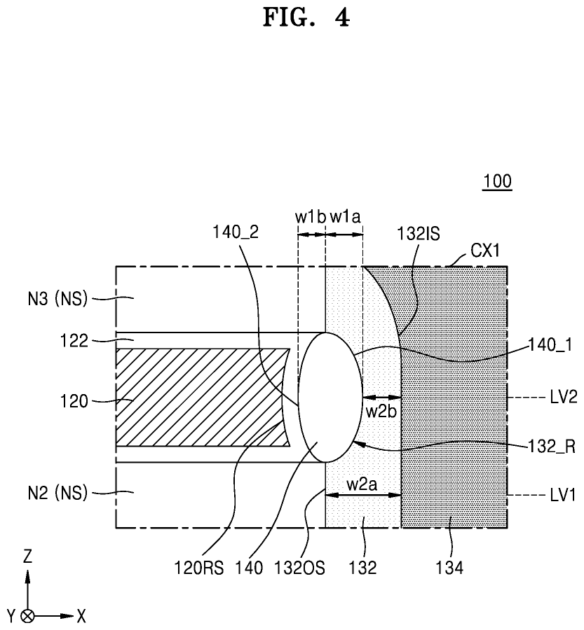

FIG. 1 is a schematic layout diagram of an integrated circuit device 100 according to some embodiments. FIG. 2 is a cross-sectional view taken along line A1-A1′ in FIG. 1. FIG. 3 is a cross-sectional view taken along line A2-A2′ in FIG. 1 and FIG. 4 is an enlarged view of a region CX1 in FIG. 2.

Referring to FIGS. 1 to 4, the integrated circuit device 100 may include a transistor TRI on a substrate 110. The transistor TRI may form a logic cell including a multi-bridge channel field-effect transistor (MBCFET). In some embodiments, the transistor TRI may be a p-type metal-oxide semiconductor (PMOS) transistor or an n-type MOS (NMOS) transistor.

In some embodiments, the substrate 110 may include a Group IV semiconductor such as Si or Ge, a Group IV-IV compound semiconductor such as SiGe or SiC, or a Group III-V compound semiconductor such as GaAs, InAs, or InP. A plurality of fin-type active regions FA may protrude from a first surface 110F of the substrate 110 and extend in a first horizontal direction (the X direction).

An isolation film 112 may be on the first surface 110F of the substrate 100 and may cover the lower side surfaces of the fin-type active regions FA. The isolation film 112 may fill an isolation trench 112T, which extends from an upper surface of the fin-type active regions FA into the substrate 110. For example, the isolation film 112 may have a double-layer structure of an interfacial layer (not shown) and a buried insulating layer (not shown).

In some embodiments, a plurality of semiconductor patterns NS may be above the fin-type active regions FA and separated from each other in the vertical direction (the Z direction). Each of the semiconductor patterns NS may include a Group IV semiconductor such as Si or Ge, a Group IV-IV compound semiconductor such as SiGe or SiC, or a Group III-V compound semiconductor such as GaAs, InAs, or InP.

The semiconductor patterns NS may have a relatively large width in a second horizontal direction (the Y direction) and have a relatively small thickness in the vertical direction (the Z direction) and may have, for example, a nanosheet shape. For example, as shown in FIG. 2, the semiconductor patterns NS may include a first nanosheet N1, a second nanosheet N2, and a third nanosheet N3, which may be separated from each other in the vertical direction (the Z direction) above the fin-type active regions FA. However, the number of semiconductor patterns NS is not limited to an example shown in FIG. 2. Each of the semiconductor patterns NS may function as a channel region.

In some embodiments, each of the semiconductor patterns NS may have a width of about 5 nm to about 100 nm in the second horizontal direction (the Y direction) and a thickness of about 1 nm to about 10 nm in the vertical direction (the Z direction) but the present disclosure is not limited thereto. In some embodiments, at least one of the semiconductor patterns NS may have a different thickness in the vertical direction (the Z direction) than the other semiconductor patterns NS.

A plurality of gate lines 120 may extend in the second horizontal direction (the Y direction) to surround the semiconductor patterns NS and may be separated from each other at a first gate pitch CPP in the first horizontal direction (the X direction).

In some embodiments, the gate lines 120 may include a doped polysilicon, metal, a conductive metal nitride, a conductive metal carbide, or a conductive metal silicide, or a combination of two or more thereof. For example, the gate lines 120 may include Al, Cu, Ti, Ta, W, Mo, TaN, NiSi, CoSi, TiN, WN, TiAl, TiAlN, TaCN, TaC, or TaSiN, or a combination of two or more thereof but the present disclosure is not limited thereto. In some embodiments, the gate lines 120 may include a work function metal layer (not shown) and a gap-fill metal film (not shown). The work function metal layer may include at least one metal selected from the group consisting of Ti, W, Ru, Nb, Mo, Hf, Ni, Co, Pt, Yb, Tb, Dy, Er, and Pd. The gap-fill metal film may include a W film or an Al film. In some embodiments, the gate lines 120 may have a stack structure of TiAlC/TiN/W, a stack structure of TiN/TaN/TiAlC/TiN/W, or a stack structure of TiN/TaN/TiN/TiAlC/TiN/W but the present disclosure is not limited thereto.

In some embodiments, each of the gate lines 120 may include a main gate portion 120M covering the topmost semiconductor pattern NS and a sub gate portion 120S between two adjacent semiconductor patterns NS. For example, the main gate portion 120M may cover the top surface of the third nanosheet N3 and the sub gate portion 120S may be between the fin-type active region FA and the first nanosheet N1, between the first nanosheet N1 and the second nanosheet N2, and between the second nanosheet N2 and the third nanosheet N3.

A gate insulating layer 122 may be between the gate lines 120 and the semiconductor patterns NS. For example, the gate insulating layer 122 may be between the main gate portion 120M of each of the gate lines 120 and the topmost semiconductor pattern NS, between the sub gate portion 120S and each of the semiconductor patterns NS, and between the sub gate portion 120S and the top surface of the fin-type active regions FA.

In some embodiments, the gate insulating layer 122 may include a silicon oxide film, a silicon oxynitride film, or a high-k dielectric film having a higher dielectric constant than the silicon oxide film, or a combination of two or more thereof. The high-k dielectric film may include metal oxide or metal oxynitride. For example, the high-k dielectric film that may be used for the gate insulating layer 122 may include HfO₂, HfSiO, HfSiON, HfTaO, HfTiO, HfZrO, ZrO₂, or Al₂O₃, or a combination of two or more thereof, but the present disclosure is not limited thereto.

An outer insulating spacer 124 may be on a sidewall of the main gate portion 120M of each of the gate lines 120. The outer insulating spacer 124 may be on opposite ends of the topmost semiconductor pattern NS and separated from each gate line 120 by the gate insulating layer 122. In some embodiments, the outer insulating spacer 124 may include silicon oxide (SiOₓ), silicon nitride (SiNₓ), silicon oxynitride (SiOₓN_{y}), silicon carbonitride (SiCₓN_{y}), or silicon oxycarbonitride (SiOₓC_{y}N_{z}), or a combination of two or more thereof.

A plurality of recesses RS may be respectively at opposite sides of each of the gate lines 120 and may extend into the fin-type active regions FA. A plurality of source/drain regions 130 may be respectively in the recesses RS. Each of the source/drain regions 130 may be in one of the recesses RS and connected to opposite ends of each of the semiconductor patterns NS.

In some embodiments, each of the source/drain regions 130 may include a buffer layer 132, a main semiconductor layer 134, and a capping layer 136. In some embodiments, the buffer layer 132 may be on the inner wall of each of the recesses RS and in contact (e.g., direct contact) with the semiconductor patterns NS. The main semiconductor layer 134 may be in (e.g., fill) each of the recesses RS and may have a top surface at a higher level than the topmost semiconductor pattern NS. The capping layer 136 may cover the top surface of the main semiconductor layer 134 and have a relatively small thickness.

In some embodiments, the buffer layer 132 may include a semiconductor material including a first element as a dopant. In some embodiments, the first element may include at least one material or element selected from the group consisting of fluorine, oxygen, argon, and nitrogen. For example, the buffer layer 132 may include at least one selected from the group consisting of fluorine-doped Si, fluorine-doped SiGe, fluorine-doped SiP, fluorine-doped SiGeB, oxygen-doped Si, oxygen-doped SiGe, oxygen-doped SiP, oxygen-doped SiGeB, argon-doped Si, argon-doped SiGe, argon-doped SiP, argon-doped SiGeB, nitrogen-doped Si, nitrogen-doped SiGe, nitrogen-doped SiP, and nitrogen-doped SiGeB.

In some embodiments, the main semiconductor layer 134 may include at least one semiconductor material selected from the group consisting of SiGe, SiP, and SiGeB. The main semiconductor layer 134 may not include the first element as a dopant. In some embodiments, when the buffer layer 132 includes fluorine-doped Si, the main semiconductor layer 134 may include SiP, SiGe, or SiGeB. In some embodiments, when the buffer layer 132 includes fluorine-doped SiP, the main semiconductor layer 134 may include SiP having a greater P content than the buffer layer 132. In some embodiments, when the buffer layer 132 includes fluorine-doped SiGeB, the main semiconductor layer 134 may include SiGeB having a greater Ge content and/or a greater B content than the buffer layer 132.

In some embodiments, the capping layer 136 may include a semiconductor material, e.g., doped or undoped silicon. The capping layer 136 may cover the top surface and the sidewall of the main semiconductor layer 134.

An inner spacer 140 may be between the sub gate portion 120S of a gate line 120 and a source/drain region 130. The inner spacer 140 may be between two adjacent semiconductor patterns NS and between the source/drain region 130 and the sub gate portion 120S of the gate line 120 facing the source/drain region 130.

In some embodiments, the inner spacer 140 may include an oxide formed from a portion of the buffer layer 132 by an oxidation process or a nitride formed from a portion of the buffer layer 132 by a nitridation process. In some embodiments, the inner spacer 140 may include oxide of at least one material selected from the group consisting of fluorine-doped Si, fluorine-doped SiGe, fluorine-doped SiP, fluorine-doped SiGeB, oxygen-doped Si, oxygen-doped SiGe, oxygen-doped SiP, oxygen-doped SiGeB, argon-doped Si, argon-doped SiGe, argon-doped SiP, and argon-doped SiGeB or nitride of at least one material selected from the group consisting of nitrogen-doped Si, nitrogen-doped SiGe, nitrogen-doped SiP, and nitrogen-doped SiGeB. In some embodiments, the inner spacer 140 may include SiOₓF_{y}. In some embodiments, the inner spacer 140 may include SiNₓ.

The inner spacer 140 may include a first sidewall 140_1 that protrudes toward the source/drain region 130 and a second sidewall 140_2 that protrudes toward the gate line 120. The first sidewall 140_1 and the second sidewall 140_2 may have a convex curved shape. For example, the first sidewall 140_1 of the inner spacer 140 may be convex and may be in contact with the buffer layer 132 of the source/drain region 130. The second sidewall 140_2 of the inner spacer 140 may be between two adjacent semiconductor patterns NS (or between a bottommost semiconductor pattern NS and the fin-type active region FA) and may protrude toward the gate line 120. A sidewall 120RS of the gate line 120 facing the second sidewall 140_2 of the inner spacer 140 may have a concave profile toward the inside of the gate line 120, wherein the concave profile corresponds to the concave shape of the second sidewall 140_2 of the inner spacer 140.

For example, the first sidewall 140_1 of the inner spacer 140 may be separated from the sidewall of the semiconductor patterns NS by a first distance w1a in the first horizontal direction (the X direction) and the second sidewall 140_2 of the inner spacer 140 may be separated from the sidewall of the semiconductor patterns NS by a second distance w1b in the first horizontal direction (the X direction). Here, the first distance w1a may refer to the maximum distance between the sidewall of the semiconductor patterns NS and the first sidewall 140_1 of the inner spacer 140, for example, the distance between the center of the first sidewall 140_1 of the inner spacer 140 and the sidewall of the semiconductor patterns NS in the first horizontal direction (the X direction). The second distance w1b may refer to the maximum distance between the sidewall of the semiconductor patterns NS and the second sidewall 140_2 of the inner spacer 140, for example, the distance between the center of the second sidewall 140_2 of the inner spacer 140 and the sidewall of the semiconductor patterns NS in the first horizontal direction (the X direction).

In some embodiments, the buffer layer 132 may include a semiconductor material including the first element as a dopant. Accordingly, when an oxidation process or a nitridation process is performed on the exposed surface of the buffer layer 132, the oxidation or nitridation reaction of the buffer layer 132 may be accelerated or promoted so that the thickness or volume of the inner spacer 140 formed from the buffer layer 132 may relatively large. For example, the inner spacer 140 may be formed from a portion of the buffer layer 132 having a relatively large depth toward the inside of the buffer layer 132 from the exposed surface thereof. In some embodiments, the first distance w1a may be greater than the second distance w1b, as shown in FIG. 4. In some embodiments, in contrast to FIG. 4, the first distance w1a may be less than the second distance w1b.

In some embodiments, the buffer layer 132 may include a plurality of grooves 132_R in an outer sidewall 132OS thereof, wherein the grooves 132_R are separated from each other in the vertical direction (the Z direction). Each of the grooves 132_R may be in contact with the first sidewall 140_1 of the inner spacer 140 and may conform to the shape of the first sidewall 140_1 of the inner spacer 140. An inner sidewall 132IS of the buffer layer 132 may have a relatively smooth and vertically extending flat profile. As the grooves 132_R are formed in the outer sidewall 132OS of the buffer layer 132, a first width w2a in the first horizontal direction (the X direction) of the buffer layer 132 at a first vertical level LV1 coplanar with a portion of the semiconductor patterns NS may be greater than a second width w2b in the first horizontal direction (the X direction) of the buffer layer 132 at a second vertical level LV2 coplanar with a portion of the gate line 120. In some embodiments, the first width w2a in the first horizontal direction (the X direction) of the buffer layer 132 at the first vertical level LV1 coplanar with a portion of the semiconductor patterns NS may be greater than or equal to 0.5 nm.

In some embodiments, a first distance between the main semiconductor layer 134 and a sidewall of the semiconductor patterns NS in the first horizontal direction (the X direction) may be greater than a second distance between the main semiconductor layer 134 and the inner spacer 140. For example, the first distance may refer to the shortest distance between the main semiconductor layer 134 and the sidewall of the semiconductor patterns NS at the first vertical level LV1 and the second distance may refer to the shortest distance between the main semiconductor layer 134 and the inner spacer 140 at the second vertical level LV2.

A gate capping layer 126 may be on the plurality of gate lines 120 and a plurality of outer insulating spacers 124. A passivation layer 142 and an intergate insulating layer 144 may be between the gate lines 120 to cover the source/drain region 130. In some embodiments, the passivation layer 142 and the intergate insulating layer 144 may include silicon oxide (SiOₓ), silicon nitride (SiNₓ), silicon oxynitride (SiOₓN_{y}), silicon carbonitride (SiCₓN_{y}), or silicon oxycarbonitride (SiOₓC_{y}N_{z}), or a combination of two or more thereof.

Although not shown, a back-end-of-line (BEOL) structure may be on the gate capping layer 126 and the intergate insulating layer 144. The BEOL structure may include a contact, which is electrically connected to the source/drain region 130 and/or the gate line 120, a via connected to the contact, and a metal wire connected to the via.

In some embodiments, a backside power delivery network may be further provided on the bottom of the substrate 110. A connection structure such as a via contact may be further provided to connect the backside power delivery network to the top or bottom surface of the source/drain region 130.

In general, in an MBCFET including a plurality of semiconductor patterns, it may be very difficult to form a gate line surrounding the semiconductor patterns. In particular, an electrical short-circuit between a source/drain region and the gate line is likely to occur in a process of replacing a sacrificial pattern between the semiconductor patterns with the gate line. To prevent the electrical short-circuit, a method of forming an inner spacer before forming a source/drain region has been proposed. However, a process of forming an inner spacer may be complicated, and the crystal quality of a source/drain region may decrease or degrade due to the presence of the inner spacer during an epitaxy process for forming the source/drain region.

However, according to the embodiments described above, the buffer layer 132 at the boundary between the source/drain region 130 and the semiconductor patterns NS may be formed by using a semiconductor material including the first element, and thereafter, the inner spacer 140 having a relatively large thickness may be formed by performing an oxidation process or a nitridation process on the buffer layer 132 after removing a dummy gate line. Because the inner spacer 140 having a relatively large thickness may be formed from a portion of the buffer layer 132 doped with the first element such as fluorine, a bridge defect or an electrical short-circuit may be prevented from occurring between the gate line 120 and the source/drain region 130. In addition, because the inner spacer 140 is formed after the source/drain region 130 is formed, the crystal quality of the source/drain region 130 may increase.

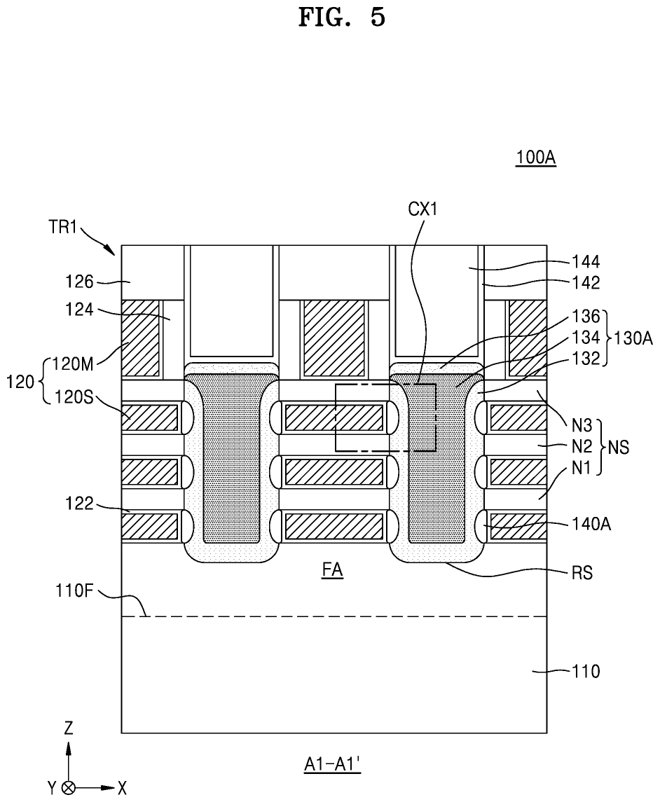

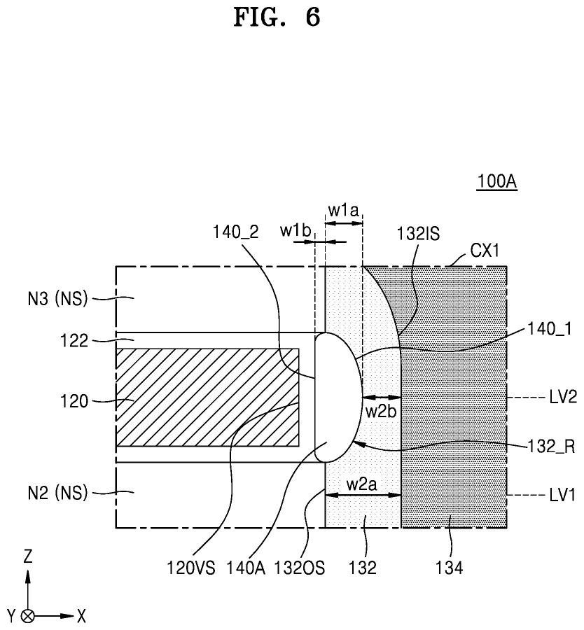

FIG. 5 is a cross-sectional view of an integrated circuit device 100A according to some embodiments. FIG. 6 is an enlarged view of a region CX1 in FIG. 5.

Referring to FIGS. 5 and 6, an inner spacer 140A may include a first sidewall 140_1 that protrudes toward a source/drain region 130A and a second sidewall 140_2 that protrudes toward a gate line 120. The first sidewall 140_1 may have a convex curved shape and the second sidewall 140_2 may have a relatively flat shape. For example, the first sidewall 140_1 of the inner spacer 140A may be convex and may be in contact with a buffer layer 132 of the source/drain region 130A. The second sidewall 140_2 of the inner spacer 140A may have a portion extending in the vertical direction Z between two adjacent semiconductor patterns NS. A sidewall 120VS of the gate line 120 facing the second sidewall 140_2 of the inner spacer 140A may have a vertical profile.

For example, the first sidewall 140_1 of the inner spacer 140A may be separated from the sidewall of the semiconductor patterns NS by a first distance w1a in the first horizontal direction (the X direction) and the second sidewall 140_2 of the inner spacer 140A may be separated from the sidewall of the semiconductor patterns NS by a second distance w1b in the first horizontal direction (the X direction). The second distance w1b may be less than the first distance w1a.

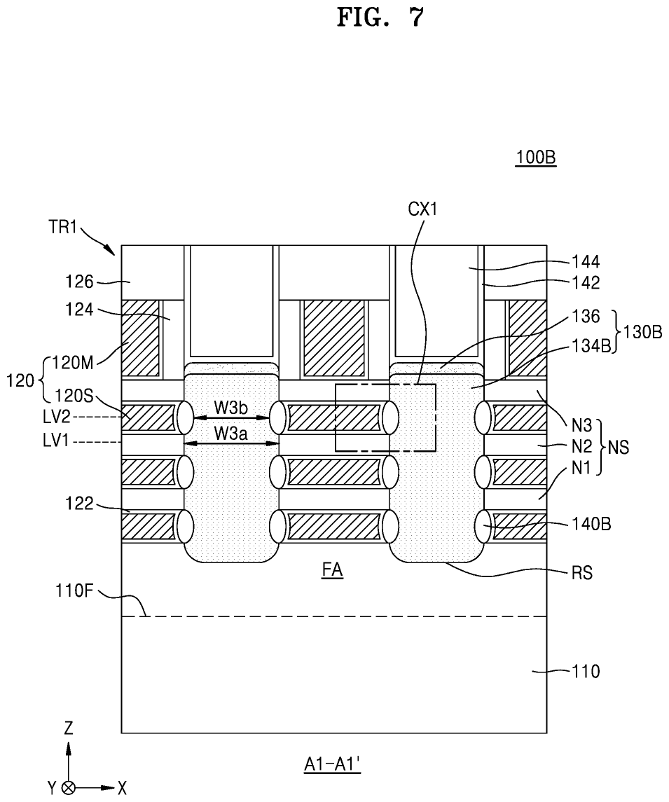

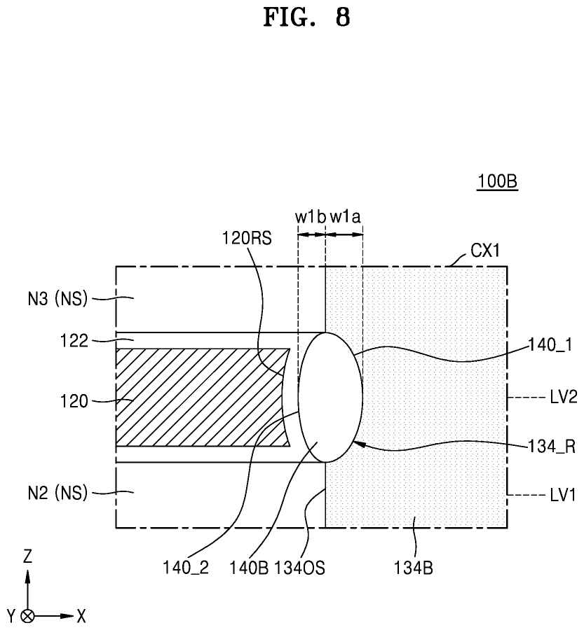

FIG. 7 is a cross-sectional view of an integrated circuit device 100B according to some embodiments. FIG. 8 is an enlarged view of a region CX1 in FIG. 7.

Referring to FIGS. 7 and 8, a source/drain region 130B may include a main semiconductor layer 134B and a capping layer 136. For example, the source/drain region 130B may be different from the source/drain region 130 described with reference to FIGS. 1 to 4 in that the source/drain region 130B does not include a buffer layer 132. The main semiconductor layer 134B may be on the bottom and sidewall of each of a plurality of recesses RS, may be in (e.g., fill) each recess RS, and may be in contact with end portions of a plurality of semiconductor patterns NS.

An inner spacer 140B may include a first sidewall 140_1 that protrudes toward a source/drain region 130B and a second sidewall 140_2 that protrudes toward a gate line 120. The first sidewall 140_1 may have a convex curved shape and the second sidewall 140_2 may have a convex curved shape with a profile that protrudes less than the first sidewall 140_1. For example, the first sidewall 140_1 of the inner spacer 140B may be convex and may be in contact with the main semiconductor layer 134B of the source/drain region 130B. The second sidewall 140_2 of the inner spacer 140B may be convex toward the sub gate portion 120S between two adjacent semiconductor patterns NS.

In some embodiments, the main semiconductor layer 134B may include a semiconductor material including the first element as a dopant. In some embodiments, the first element may include at least one material or element selected from the group consisting of fluorine, oxygen, argon, and nitrogen. For example, the main semiconductor layer 134B may include at least one selected from the group consisting of fluorine-doped Si, fluorine-doped SiGe, fluorine-doped SiP, fluorine-doped SiGeB, oxygen-doped Si, oxygen-doped SiGe, oxygen-doped SiP, oxygen-doped SiGeB, argon-doped Si, argon-doped SiGe, argon-doped SiP, argon-doped SiGeB, nitrogen-doped Si, nitrogen-doped SiGe, nitrogen-doped SiP, and nitrogen-doped SiGeB.

The main semiconductor layer 134B may include a plurality of grooves 132_R in an outer sidewall 134OS thereof, wherein the grooves 132_R are separated from each other in the vertical direction (the Z direction). Each of the grooves 132_R may be in contact with the first sidewall 140_1 of the inner spacer 140B and may conform to the shape of the first sidewall 140_1 of the inner spacer 140B. As the grooves 132_R are formed in the outer sidewall 1340S of the main semiconductor layer 134B, a first width W3a in the first horizontal direction (the X direction) of the main semiconductor layer 134B at a first vertical level LV1 coplanar with a portion of the semiconductor patterns NS may be greater than a second width W3b in the first horizontal direction (the X direction) of the main semiconductor layer 134B at a second vertical level LV2 coplanar with a portion of the gate line 120.

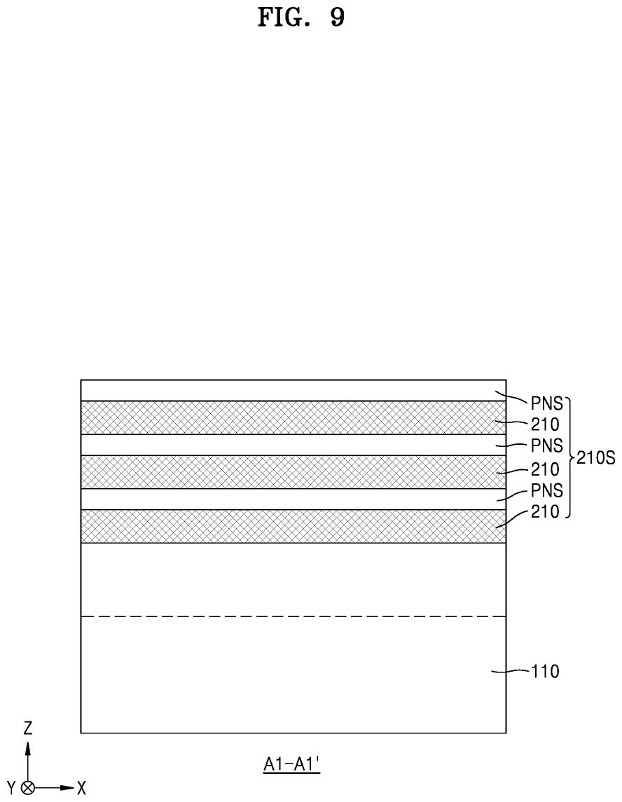

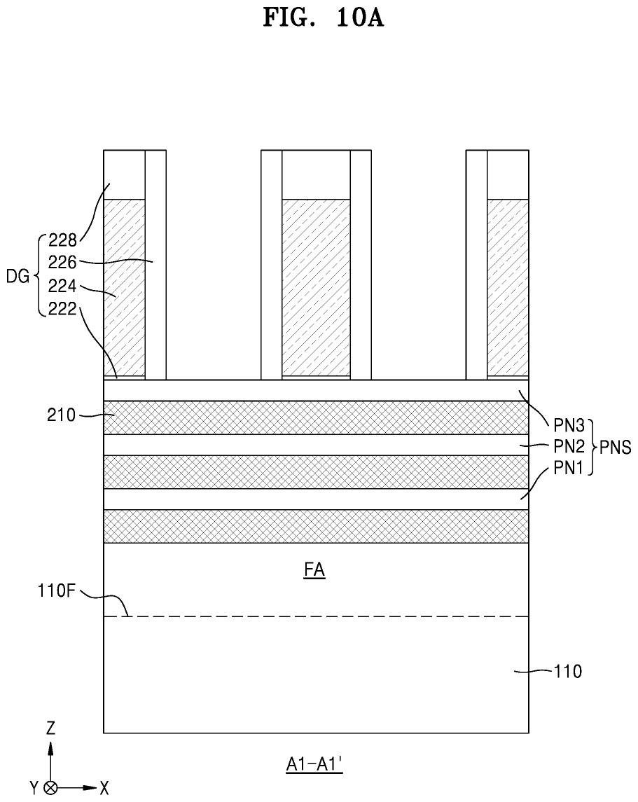

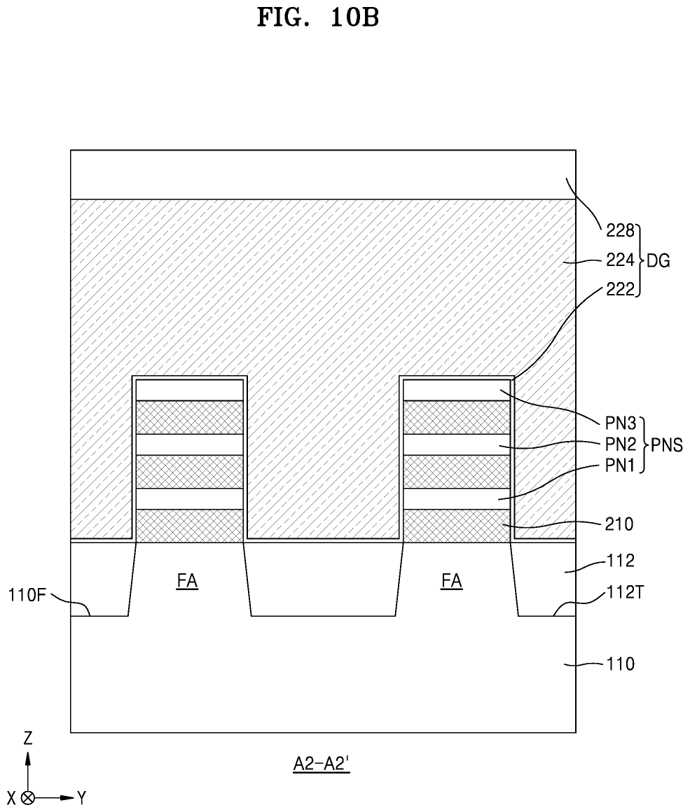

FIGS. 9 to 16B are cross-sectional views of stages in a method of manufacturing an integrated circuit device, according to some embodiments. In greater detail, FIGS. 9, 10A, 11, 12, 13, 14A, 15, and 16A are cross-sectional views corresponding to the cross-section taken along line A1-A1′ in FIG. 1 and FIGS. 10B, 14B, and 16B are cross-sectional views corresponding to the cross-section taken along line A2-A2′ in FIG. 1.

Referring to FIG. 9, a sacrificial layer 210 and a channel semiconductor layer PNS may be alternately and sequentially formed on the top surface of the substrate 110. A stack structure of the sacrificial layer 210 and the channel semiconductor layer PNS may be referred to as a channel semiconductor stack 210S.

In some embodiments, the sacrificial layer 210 and the channel semiconductor layer PNS may be formed by an epitaxy process. In some embodiments, the sacrificial layer 210 may include a material having an etch selectivity with respect to the channel semiconductor layer PNS. For example, each of the sacrificial layer 210 and the channel semiconductor layer PNS may include a monocrystalline layer of a Group IV semiconductor, a Group IV-IV compound semiconductor, or a Group III-V compound semiconductor. The sacrificial layer 210 may include a different material than the channel semiconductor layer PNS. In some embodiments, the sacrificial layer 210 may include SiGe and the channel semiconductor layer PNS may include monocrystalline silicon.

In some embodiments, the epitaxy process may include vapor-phase epitaxy (VPE), chemical vapor deposition (CVD) such as ultra-high vacuum CVD (UHV-CVD), or molecular beam epitaxy, or a combination of two or more thereof. In the epitaxy process, a liquid or gaseous precursor may be used to form the sacrificial layer 210 and the channel semiconductor layer PNS.

Referring to FIGS. 10A and 10B, after a hardmask pattern (not shown) is formed on a topmost channel semiconductor layer PNS to extend with a certain length in the first horizontal direction (the X direction), the sacrificial layer 210, the channel semiconductor layer PNS, and the substrate 110 may be etched by using the hardmask pattern as an etch mask. A stack structure of the channel semiconductor layer PNS and the sacrificial layer 210 may have a line pattern shape extending in the first horizontal direction (the X direction). An isolation trench 112T may be formed in the substrate 110 between stack line patterns of the channel semiconductor layer PNS and the sacrificial layer 210.

For example, the channel semiconductor layer PNS may include a first channel semiconductor layer PN1, a second channel semiconductor layer PN2, and a third channel semiconductor layer PN3, which are above the first surface 110F of the substrate 110 and separated from each other in the vertical direction Z. The sacrificial layer 210 may be between the top surface of the substrate 110 and the first channel semiconductor layer PN1, between the first channel semiconductor layer PN1 and the second channel semiconductor layer PN2, and between the second channel semiconductor layer PN2 and the third channel semiconductor layer PN3.

Thereafter, the isolation trench 112T may be filled with an insulating material and an upper portion of the insulating material may be planarized such that an isolation film 112 filling the isolation trench 112T may be formed. A fin-type active region FA may be defined in the substrate 110 by the isolation film 112.

Thereafter, a sacrificial gate structure DG may be formed on the isolation film 112 and the stack line patterns of the channel semiconductor layer PNS and the sacrificial layer 210. The sacrificial gate structure DG may include a sacrificial insulation layer pattern 222, a sacrificial gate line 224, a sacrificial gate spacer 226, and a sacrificial gate capping layer 228.

The sacrificial insulation layer pattern 222 may extend in the second horizontal direction (the Y direction) and may be formed on and conform to the shapes of the top surfaces and sidewalls of the stack line patterns of the channel semiconductor layer PNS and the sacrificial layer 210 and the top surface of the isolation film 112. In some embodiments, the sacrificial insulation layer pattern 222 may include a material having an etch selectivity with respect to the sacrificial gate line 224. The sacrificial insulation layer pattern 222 may include at least one selected from the group consisting of thermal oxide, silicon oxide, and silicon nitride.

The sacrificial gate line 224 may be formed relatively high on the sacrificial insulation layer pattern 222 and may cover the stack line patterns of the channel semiconductor layer PNS and the sacrificial layer 210. The top surface of the sacrificial gate line 224 may have a flat level. In some embodiments, the sacrificial gate line 224 may include polysilicon but the present disclosure is not limited thereto.

The sacrificial gate spacer 226 may be on a sidewall of the sacrificial gate line 224. In some embodiments, the sacrificial gate spacer 226 may include silicon oxide (SiOₓ), silicon nitride (SiNₓ), silicon oxynitride (SiOₓN_{y}), silicon carbonitride (SiCₓN_{y}), or silicon oxycarbonitride (SiOₓC_{y}N_{z}), or a combination of two or more thereof.

The sacrificial gate capping layer 228 may be on the top surface of the sacrificial gate line 224. Opposite sidewalls of the sacrificial gate capping layer 228 may be covered with the sacrificial gate spacer 226. In some embodiments, the sacrificial gate capping layer 228 may include a silicon nitride film.

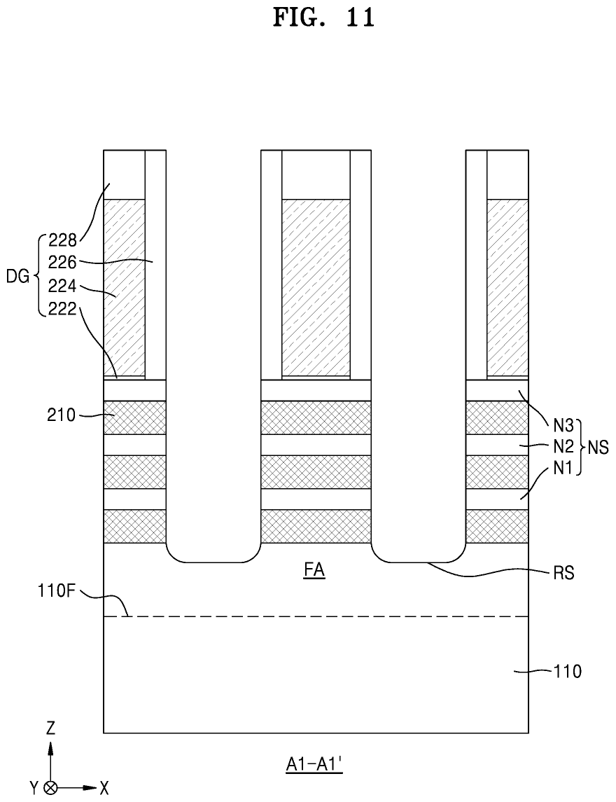

Referring to FIG. 11, a recess RS may be formed at each of the opposite sides of the sacrificial gate structure DG by etching the stack line patterns of the channel semiconductor layer PNS and the sacrificial layer 210 and a portion of the substrate 110 at each of the opposite sides of the sacrificial gate structure DG. As the recess RS is formed, the channel semiconductor layer PNS may be divided into a plurality of semiconductor patterns NS. For example, as the recess RS is formed, a structure in which a plurality of sacrificial layers 210 alternate with the semiconductor patterns NS may be formed on the fin-type active region FA.

In some embodiments, as shown in FIG. 11, the recess RS may include sidewalls that are respectively aligned with and continuously extend from the opposite sidewalls of the sacrificial gate structure DG, e.g., the opposite sidewalls of the sacrificial gate spacer 226. For example, a sidewall of each of the semiconductor patterns NS exposed by the recess RS may be aligned with a sidewall of the sacrificial gate spacer 226 and thus form a continuous side wall profile.

FIG. 11 illustrates an example in which the recess RS has substantially the same width throughout the entire height thereof and has a vertical sidewall profile such that the semiconductor patterns NS have substantially the same width in the first horizontal direction (the X direction). However, in some embodiments, a lower width of the recess RS may be less than an upper width thereof and the recess RS may have an oblique sidewall profile, and accordingly, at least one of the semiconductor patterns NS (e.g., the bottommost semiconductor pattern NS or the first nanosheet N1) may have a larger width than the other semiconductor patterns NS.

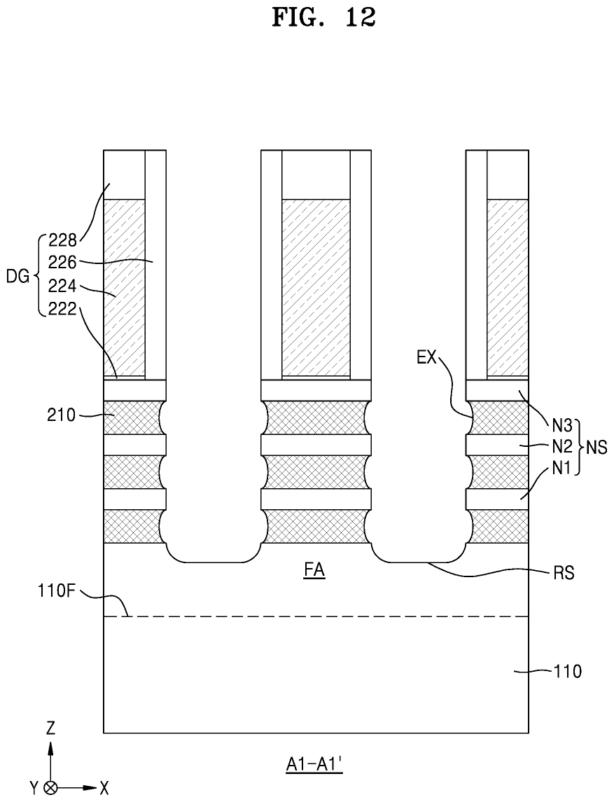

Referring to FIG. 12, an indentation EX may be formed by removing a portion of the sacrificial layer 210 exposed on the sidewall of the recess RS. For example, a portion of the sacrificial layer 210 may be removed by performing wet etching or dry etching under etching conditions with selective etching properties for the sacrificial layer 210. In some embodiments, the indentation EX may refer to a sidewall portion of the sacrificial layer 210 receding inward from the sidewall of the semiconductor patterns NS or a space provided by a sidewall portion of the sacrificial layer 210 receding inward between two semiconductor patterns NS adjacent to each other in the vertical direction Z.

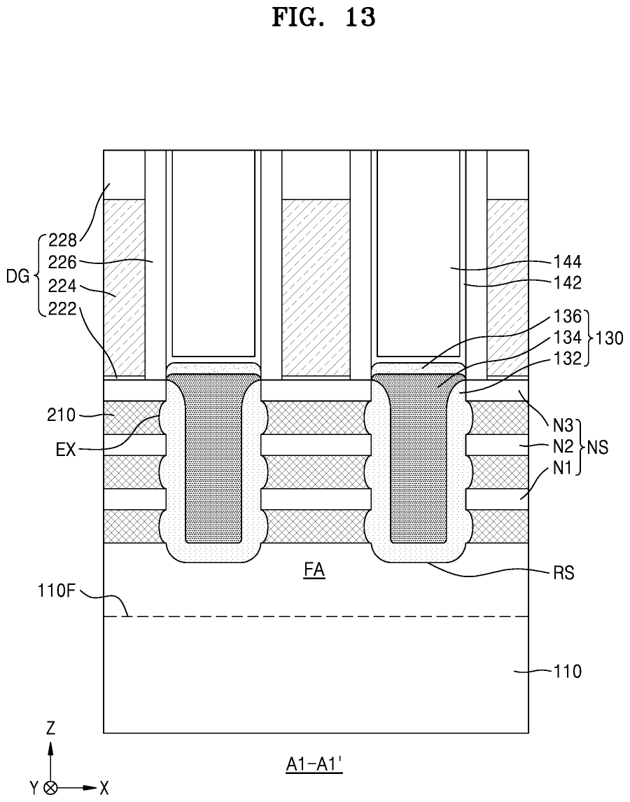

Referring to FIG. 13, a source/drain region 130 may be formed in the recess RS. For example, the source/drain region 130 may be formed by epitaxially growing a semiconductor material from the surfaces of the semiconductor patterns NS, the sacrificial layer 210, and the substrate 110, which are exposed on the inner wall of the recess RS. The source/drain region 130 may be formed by sequentially forming a buffer layer 132, a main semiconductor layer 134, and a capping layer 136 on the inner wall of the recess RS.

In some embodiments, the buffer layer 132 may be formed on the inner wall of the recess RS to have a thickness that does not completely fill the recess RS. The buffer layer 132 may be in contact with the surfaces of the semiconductor patterns NS, the sacrificial layer 210, and the substrate 110, which are exposed on the inner wall of the recess RS.

In some embodiments, the buffer layer 132 may be formed by using a semiconductor material including the first element as a dopant. In some embodiments, the first element may include at least one element or material selected from the group consisting of fluorine, oxygen, argon, and nitrogen. For example, the buffer layer 132 may include at least one selected from the group consisting of fluorine-doped Si, fluorine-doped SiGe, fluorine-doped SiP, fluorine-doped SiGeB, oxygen-doped Si, oxygen-doped SiGe, oxygen-doped SiP, oxygen-doped SiGeB, argon-doped Si, argon-doped SiGe, argon-doped SiP, argon-doped SiGeB, nitrogen-doped Si, nitrogen-doped SiGe, nitrogen-doped SiP, and nitrogen-doped SiGeB.

In some embodiments, when the first element includes fluorine, a fluorine-doped semiconductor material may be formed by supplying a certain content of a fluorine-containing precursor including F₂, NF₃, or SiF₄, or a combination or two or more thereof in an epitaxial growth process for forming the buffer layer 132. In some embodiments, when the first element includes oxygen, an oxygen-doped semiconductor material may be formed by supplying a certain content of an oxygen-containing precursor including O₂, O₃, H₂O₂, alkoxide, or O₂ plasma, or a combination of two or more thereof in an epitaxial growth process for forming the buffer layer 132. In some embodiments, when the first element includes argon, an argon-doped semiconductor material may be formed by supplying a certain content of Ar gas, or Ar plasma, or a combination thereof in an epitaxial growth process for forming the buffer layer 132. In some embodiments, when the first element includes nitrogen, a nitrogen-doped semiconductor material may be formed by supplying a certain content of a nitrogen-containing precursor including N₂, NH₃, N₂H₆, or N₂ plasma, or a combination of two or more thereof in an epitaxial growth process for forming the buffer layer 132.

The buffer layer 132 may be epitaxially grown by using, as seed layers, the exposed sidewall of the semiconductor patterns NS on the inner wall of the recess RS, the exposed sidewall of the sacrificial layer 210 on the inner wall of the recess RS (e.g., the exposed surface of the indentation EX), and the exposed top surface of the substrate 110 on the bottom of the recess RS. The whole surface exposed by the recess RS may be used as a seed layer for epitaxial growth during the process of forming the buffer layer 132, and as such crystal defects may be prevented from occurring in the buffer layer 132 during the process of forming the buffer layer 132 and the crystal quality of the buffer layer 132 may be excellent or improved.

In some embodiments, the main semiconductor layer 134 may be formed on the buffer layer 132 to have a relatively large thickness so as to fill the recess RS. The top surface of the main semiconductor layer 134 may be at a relatively higher level than the topmost semiconductor pattern NS.

In some embodiments, the main semiconductor layer 134 may include at least one semiconductor material selected from the group consisting of SiGe, SiP, and SiGeB. In some embodiments, when the buffer layer 132 includes fluorine-doped Si, the main semiconductor layer 134 may include SiP, SiGe, or SiGeB. In some embodiments, when the buffer layer 132 includes fluorine-doped SiP, the main semiconductor layer 134 may include SiP having a greater P content than the buffer layer 132. In some embodiments, when the buffer layer 132 includes fluorine-doped SiGeB, the main semiconductor layer 134 may include SiGeB having a greater Ge content and/or a greater B content than the buffer layer 132.

Because the main semiconductor layer 134 may be epitaxially grown by using the inner sidewall of the buffer layer 132 as a seed layer and the crystal quality of the buffer layer 132 is excellent or improved, a crystal defect may be prevented from occurring in the main semiconductor layer 134 during the process of forming the main semiconductor layer 134. Accordingly, the crystal quality of the main semiconductor layer 134 may also be excellent or improved.

In some embodiments, the capping layer 136 may include a semiconductor material, e.g., doped or undoped silicon. The capping layer 136 may be relatively thinly formed and may cover the top surface and the sidewall of the main semiconductor layer 134.

Thereafter, a passivation layer 142 and an intergate insulating layer 144 may be formed to cover the sacrificial gate structure DG and the source/drain region 130. The passivation layer 142 may be formed and may be relatively thin. The intergate insulating layer 144 may be formed to be relatively high and may fill the space (or remaining space) between two adjacent sacrificial gate structures DG. The top surface of the intergate insulating layer 144 may be coplanar with the top surface of the sacrificial gate structure DG.

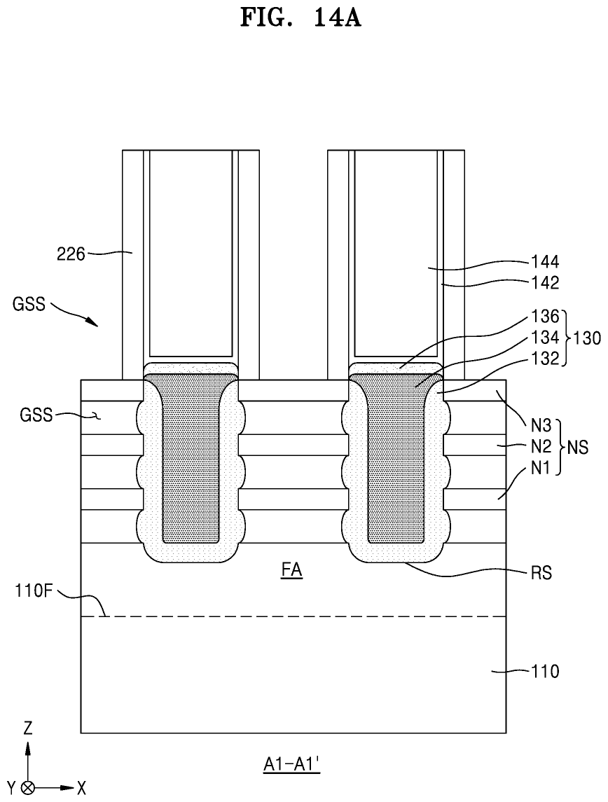

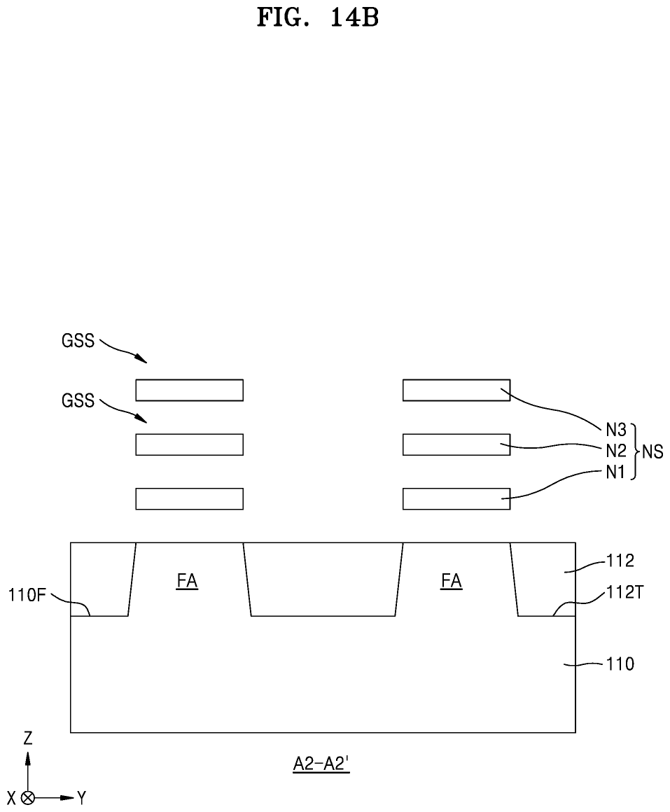

Referring to FIGS. 14A and 14B, the sacrificial gate capping layer 228 may be removed by planarizing an upper portion of the sacrificial gate structure DG and an upper portion of the intergate insulating layer 144. The top surface of the sacrificial gate line 224 may be exposed by the planarization.

Thereafter, a gate space GSS may be formed by removing the sacrificial gate line 224 and the sacrificial insulation layer pattern 222. For example, the gate space GSS may be defined between two adjacent sacrificial gate capping layers 228 and may expose the sidewalls of the semiconductor patterns NS and the sidewall of the sacrificial layer 210.

Thereafter, the semiconductor patterns NS and a portion of the top surface of the fin-type active region FA may be exposed by removing, through the gate space GSS, a plurality of sacrificial layers 210 remaining on the fin-type active region FA. The sacrificial layers 210 may be removed by wet etching that uses the difference in etch selectivity between the sacrificial layers 210 and the semiconductor patterns NS.

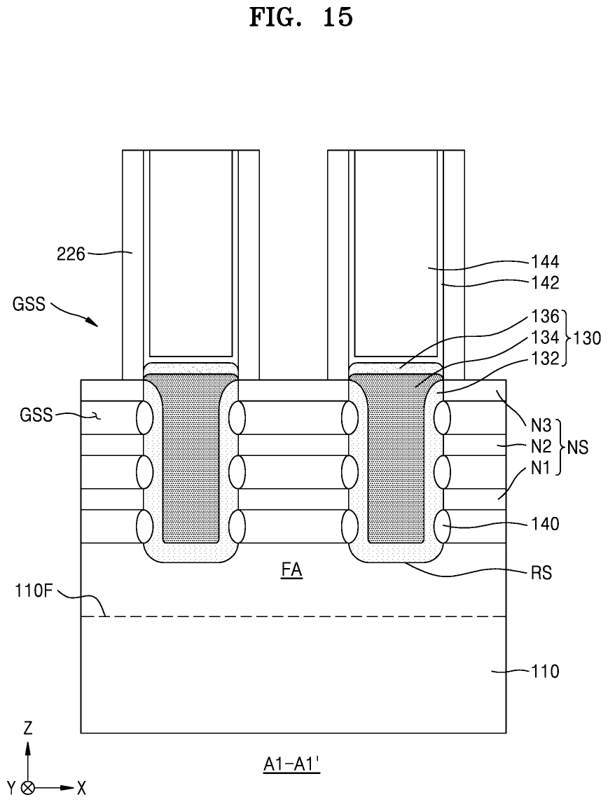

Referring to FIG. 15, an inner spacer 140 may be formed by changing a portion of the buffer layer 132 exposed by the gate space GSS into oxide or nitride by performing an oxidation process or a nitridation process on the portion of the buffer layer 132. The inner spacer 140 may be formed to have the first sidewall 140_1 (in FIG. 4) and the second sidewall 140_2 (in FIG. 4), which may protrude convexly.

In some embodiments, the inner spacer 140 may be formed by an oxidation process. At this time, the buffer layer 132 may include a semiconductor material doped with the first element and the first element may accelerate or quicken an oxidation reaction during the oxidation process. Accordingly, the inner spacer 140 may be formed to have a relatively large width. An oxide film may be formed to a certain thickness on the surface of the semiconductor patterns NS exposed by the gate space GSS during the oxidation process. An etching process (an etching process using hydrofluoric acid (HF) as an etchant) may be additionally performed to remove the oxide film from the surface of the semiconductor patterns NS.

In some embodiments, the first element in the buffer layer 132 may include fluorine, oxygen, or argon. In this case, the inner spacer 140 may include oxide of at least one material selected from the group consisting of fluorine-doped Si, fluorine-doped SiGe, fluorine-doped SiP, fluorine-doped SiGeB, oxygen-doped Si, oxygen-doped SiGe, oxygen-doped SiP, oxygen-doped SiGeB, argon-doped Si, argon-doped SiGe, argon-doped SiP, and argon-doped SiGeB.

In some embodiments, the oxidation process may include at least one selected from the group consisting of thermal oxidation, in-situ steam generation (ISSG), wet oxidations, and thermal radical oxidation. In some embodiments, supply of an additional element may be selectively performed to supplement the first element during the oxidation process. For example, Ar gas, or Ar plasma, a combination thereof, a fluorine-containing precursor including F₂, NF₃, or SiF₄, or a combination of two or more thereof, or an oxygen-containing precursor including O₂, O₃, H₂O₂, alkoxide, or O₂ plasma, or a combination of two or more thereof may be supplied during or after the oxidation process.

In some embodiments, the inner spacer 140 may be formed by a nitridation process. At this time, the buffer layer 132 may include a semiconductor material doped with the first element and the first element may accelerate or quicken a nitridation reaction during the nitridation process. Accordingly, the inner spacer 140 may be formed to have a relatively large width. A nitride film may be formed to a certain thickness on the surface of the semiconductor patterns NS exposed by the gate space GSS during the nitridation process. An etching process (an etching process using phosphoric acid (H₃PO₄) as an etchant) may be additionally performed to remove the nitride film from the surface of the semiconductor patterns NS.

In some embodiments, the first element in the buffer layer 132 may include nitrogen. In this case, the inner spacer 140 may include nitride of at least one material selected from the group consisting of nitrogen-doped Si, nitrogen-doped SiGe, nitrogen-doped SiP, and nitrogen-doped SiGeB. In some embodiments, the nitridation process may include thermal nitridation or plasma nitridation.

In some embodiments, supply of an additional element may be selectively performed to supplement the first element during the nitridation process. For example, a nitrogen-containing precursor including N₂, NH₃, N₂H₆, or N₂ plasma, or a combination of two or more thereof may be supplied before, during, or after the nitridation process.

In some embodiments, as the inner spacer 140 is formed from a portion of the buffer layer 132, a groove 132_R may be formed at the boundary between the inner spacer 140 and the buffer layer 132. The groove 132_R may be in contact with the first sidewall 140_1 of the inner spacer 140 and may have a concave profile corresponding to the shape of the first sidewall 140_1 of the inner spacer 140.

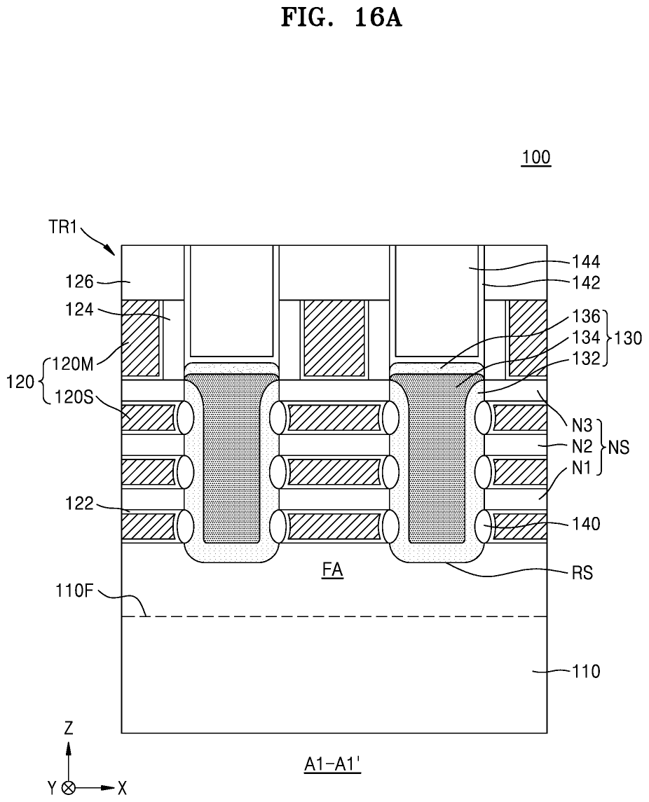

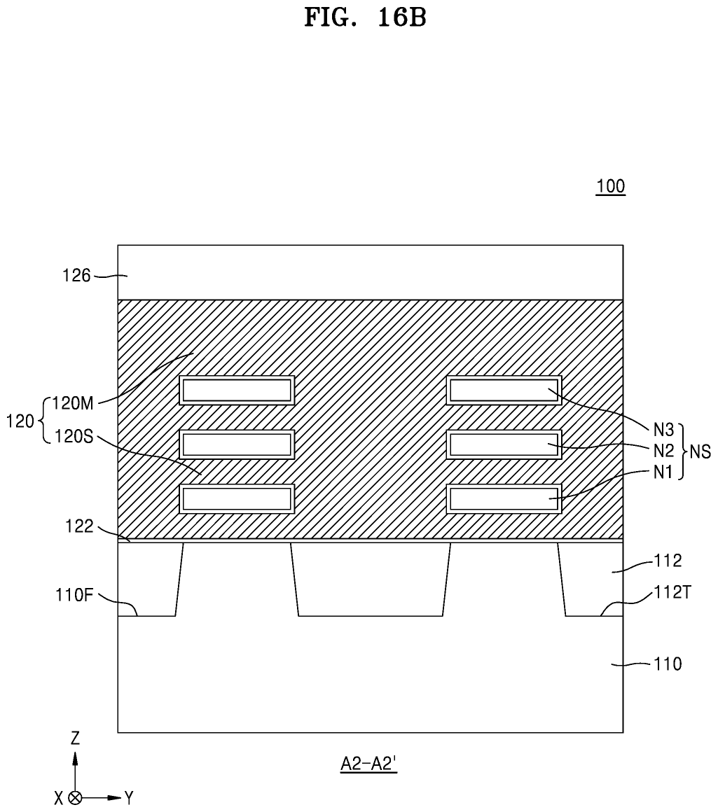

Referring to FIGS. 16A and 16B, a gate insulating layer 122 may be formed on the surface exposed by the gate space GSS. Thereafter, a gate line 120 may be formed on the gate insulating layer 122 and may fill the gate space GSS. For example, a work function conductive layer (not shown) may be formed on and conform to a shape of the inner wall of the gate space GSS, and then, a buried conductive layer (not shown) may be formed on the work function conductive layer and may fill the gate space GSS. Thereafter, an upper portion of the buried conductive layer may be planarized to expose the top surface of the intergate insulating layer 144 such that the gate line 120 may be formed.

In some embodiments, the work function conductive layer may be formed by using Al, Cu, Ti, Ta, W, Mo, TaN, NiSi, CoSi, TIN, WN, TiAl, TiAlC, TiAiN, TaCN, TaC, or TaSiN, or a combination of two or more thereof. The buried conductive layer may be formed by using Al, Cu, Ti, Ta, W, Mo, TaN, NiSi, CoSi, TiN, WN, TiAl, TiAlC, TiAlN, TaCN, TaC, or TaSiN, or a combination of two or more thereof.

Thereafter, respective upper portions of the gate line 120, the gate insulating layer 122, and the sacrificial gate spacer 226 may be removed, and then, a gate capping layer 126 may be formed in an upper portion of the gate space GSS. Here, the remaining portion of the sacrificial gate spacer 226 may be referred to as an outer insulating spacer 124.

The integrated circuit device 100 may be formed by the processes described above.

In general, an electrical short-circuit between a source/drain region and a gate line may be likely to occur in a process of replacing a sacrificial pattern between semiconductor patterns with the gate line. To prevent the electrical short-circuit, a method of forming an inner spacer before forming a source/drain region has been proposed. However, a process of forming an inner spacer is complicated, and the crystal quality of a source/drain region may decrease or degrade due to the presence of the inner spacer during an epitaxy process for forming the source/drain region.

However, according to the embodiments described above, the inner spacer 140 having a relatively large thickness may be formed from a portion of the buffer layer 132, which is doped with the first element such as fluorine, in a self-aligned manner by using an oxidation process or a nitridation process. Accordingly, a bridge defect or an electrical short-circuit may be prevented from occurring between the gate line 120 and the source/drain region 130. In addition, because the inner spacer 140 may be formed after the source/drain region 130 is formed, the crystal quality of the source/drain region 130 may increase.

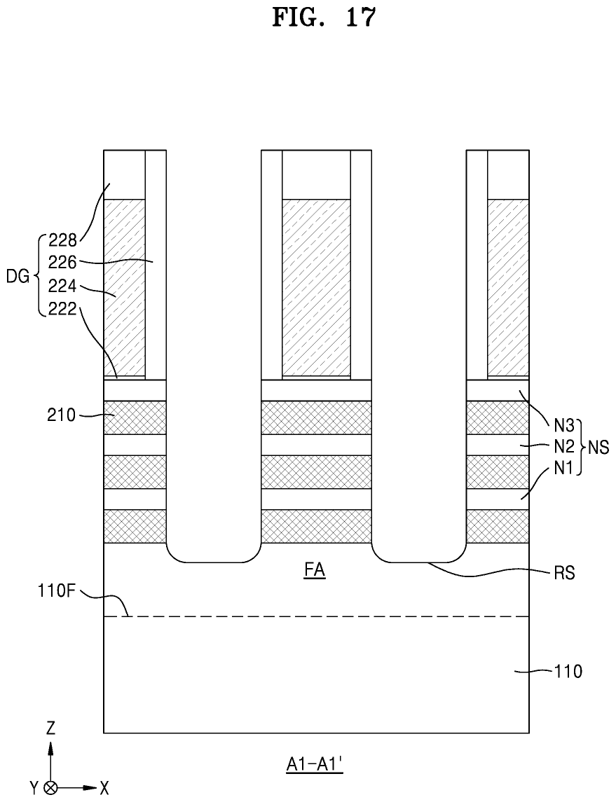

FIGS. 17 to 21 are cross-sectional views of stages in a method of manufacturing the integrated circuit device 100A, according to some embodiments.

A recess RS shown in FIG. 17 may be formed by performing the processes described above with reference to FIGS. 9 to 11.

As shown in FIG. 17, the recess RS may include sidewalls that are respectively aligned with and continuously extend from the opposite sidewalls of the sacrificial gate structure DG, e.g., the opposite sidewalls of the sacrificial gate spacer 226. For example, a sidewall of each of the semiconductor patterns NS exposed by the recess RS may be aligned with a sidewall of the sacrificial gate spacer 226 and thus form a continuous sidewall profile.

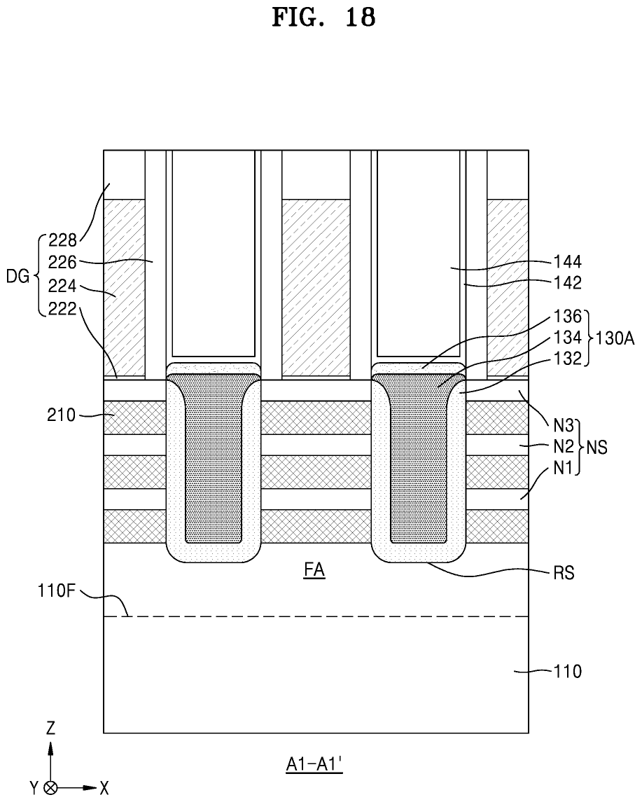

Referring to FIG. 18, a source/drain region 130A may be formed in the recess RS. For example, the source/drain region 130A may be formed by epitaxially growing a semiconductor material from the surfaces of the semiconductor patterns NS, the sacrificial layer 210, and the substrate, which may be exposed on the inner wall of the recess RS. The source/drain region 130A may be formed by sequentially forming a buffer layer 132, a main semiconductor layer 134, and a capping layer 136 on the inner wall of the recess RS.

For example, a profile, in which the sidewall of the semiconductor patterns NS is aligned with and continuously extend from the sidewall of the sacrificial layer 210, may be formed on the inner wall of the recess RS. Accordingly, the buffer layer 132 may be formed to have substantially vertical outer and inner sidewalls along the inner wall of the recess RS.

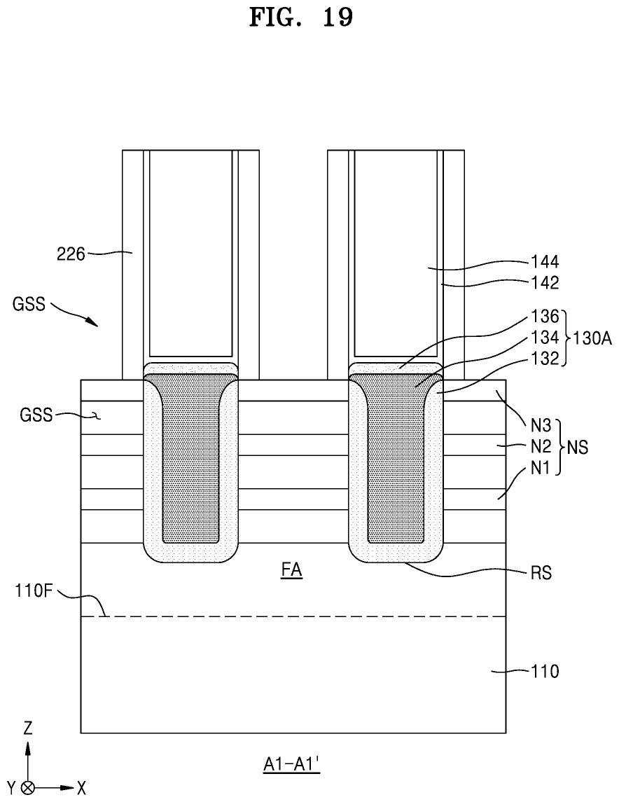

Referring to FIG. 19, a gate space GSS may be formed by removing the sacrificial gate capping layer 228, the sacrificial gate line 224, and the sacrificial insulation layer pattern 222. Thereafter, the semiconductor patterns NS and a portion of the top surface of the fin-type active region FA may be exposed by removing a plurality of sacrificial layers 210 through the gate space GSS.

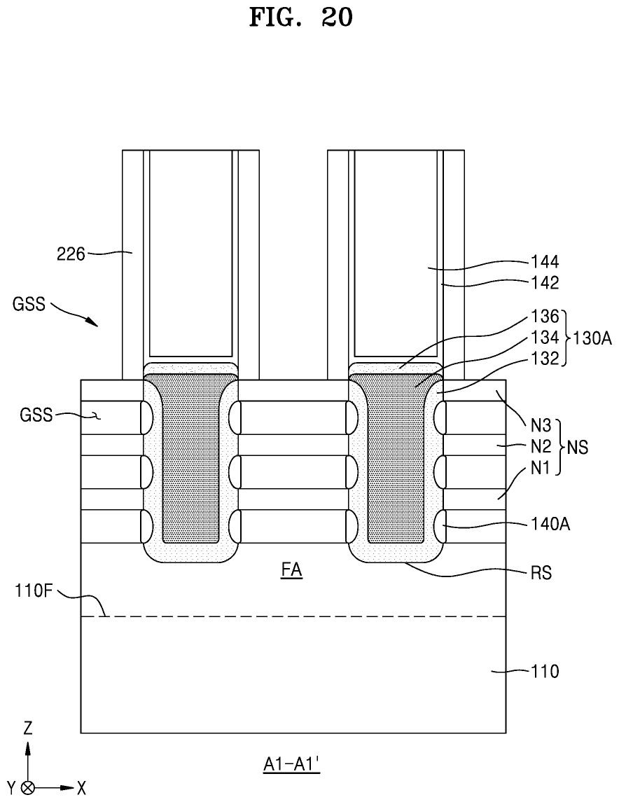

Referring to FIG. 20, an inner spacer 140A may be formed by changing a portion of the buffer layer 132 exposed by the gate space GSS into oxide or nitride by performing an oxidation process or a nitridation process on the portion of the buffer layer 132. The inner spacer 140A may be formed to have the first sidewall 140_1 (in FIG. 6), which may protrude convexly toward the source/drain region 130A, and the second sidewall 140_2 (in FIG. 6), which has a relatively flat shape (vertically extending) in a direction toward a gate line 120.

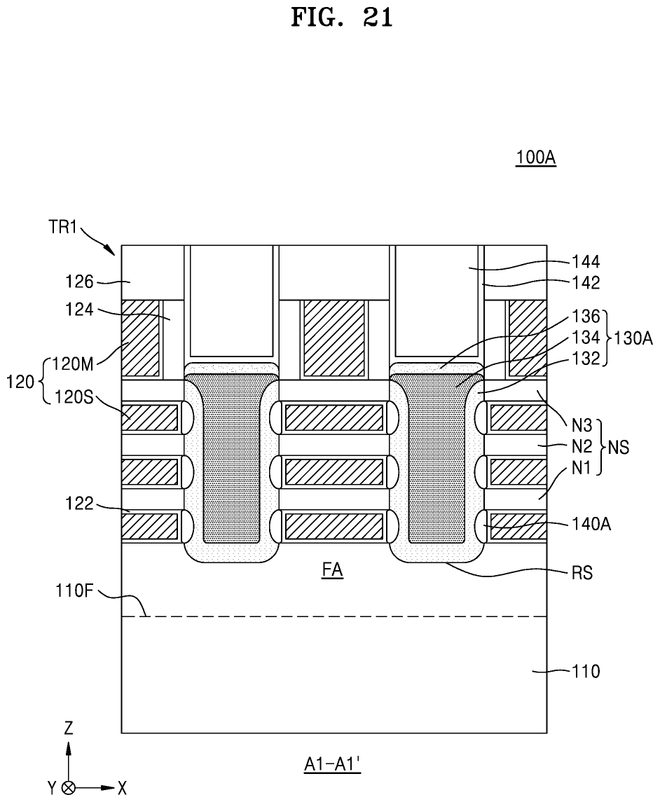

Referring to FIG. 21, a gate insulating layer 122 and a gate line 120 may be formed on the surface exposed by the gate space GSS, and a gate capping layer 126 may be formed in an upper portion of the gate space GSS.

The integrated circuit device 100A may be formed by the processes described above.

In the methods described above with reference to FIGS. 9 to 21, a structure in which the source/drain region 130 or 130A includes the buffer layer 132, the main semiconductor layer 134, and the capping layer 136 has been described. However, in some embodiments, the source/drain region 130B may include only the main semiconductor layer 134B and the capping layer 136, as described above with reference to FIGS. 7 and 8.

In this case, the recess RS may be formed by performing the processes described with reference to FIGS. 9 to 12, and the main semiconductor layer 134B may be formed on the inner wall of the recess RS to fill the recess RS. The main semiconductor layer 134B may include a semiconductor material including the first element. The main semiconductor layer 134B may have a shape which fills the indentation EX and may protrude convexly toward the sacrificial layer 210.

Thereafter, the inner spacer 140B may be formed on the surface of the main semiconductor layer 134B exposed by the gate space GSS in a self-aligned manner by using an oxidation process or a nitridation process. Accordingly, the integrated circuit device 100B described with reference to FIGS. 7 and 8 may be formed.

While the present disclosure has been particularly shown and described with reference to some examples of embodiments thereof, it will be understood that various changes in form and details may be made therein without departing from the scope of the following claims.

What is claimed is:

1. An integrated circuit device comprising:
a fin-type active region that protrudes from a substrate and extends in a first horizontal direction;
a plurality of semiconductor patterns on the fin-type active region and separated from each other in a vertical direction;
a gate line on the fin-type active region, the gate line surrounding the plurality of semiconductor patterns and extending in a second horizontal direction that intersects the first horizontal direction;
a source/drain region on the fin-type active region, adjacent to the gate line and connected to the plurality of semiconductor patterns, wherein the source/drain region includes a first semiconductor layer that contacts the plurality of semiconductor patterns, and wherein the first semiconductor layer includes a semiconductor material, the semiconductor material including a first element that includes at least one selected from the group consisting of fluorine, oxygen, argon, and nitrogen; and
an inner spacer between the source/drain region and the gate line, the inner spacer including an oxide including the first element or a nitride including the first element.

2. The integrated circuit device of claim 1, wherein the inner spacer includes:
a first sidewall that faces the source/drain region; and
a second sidewall that faces the gate line and is opposite to the first sidewall,
wherein the first sidewall of the inner spacer protrudes from a sidewall of the plurality of semiconductor patterns toward the source/drain region and has a convex profile.

3. The integrated circuit device of claim 2, wherein the first semiconductor layer includes a plurality of grooves, and wherein each of the plurality of grooves is in contact with the first sidewall of the inner spacer.

4. The integrated circuit device of claim 3, wherein the plurality of grooves are separated from each other in the vertical direction at locations corresponding to the inner spacer, and the first semiconductor layer includes a first portion and a second portion, the first portion at a same vertical level as at least a portion of the plurality of semiconductor patterns, and the second portion at a same vertical level as at least a portion of the inner spacer, and
wherein the first portion of the first semiconductor layer has a first width in the first horizontal direction, and the second portion of the first semiconductor layer has a second width that is less than the first width in the first horizontal direction.

5. The integrated circuit device of claim 4, wherein the first width of the first semiconductor layer is greater than or equal to 0.5 nanometers (nm).

6. The integrated circuit device of claim 2, wherein the gate line includes a main gate portion and a sub gate portion, the main gate portion on a topmost semiconductor pattern among the plurality of semiconductor patterns, and the sub gate portion between two adjacent semiconductor patterns among the plurality of semiconductor patterns,
wherein the inner spacer is between the sub gate portion and the first semiconductor layer.

7. The integrated circuit device of claim 6, wherein the second sidewall of the inner spacer protrudes from the sidewall of the plurality of semiconductor patterns toward the gate line and has a convex profile.

8. The integrated circuit device of claim 6, wherein a sidewall of the sub gate portion has a concave profile corresponding to a shape of the second sidewall of the inner spacer.

9. The integrated circuit device of claim 6, wherein at least a portion of the second sidewall of the inner spacer extends vertically, and a sidewall of the sub gate portion has a concave profile corresponding to a shape of the second sidewall of the inner spacer.

10. The integrated circuit device of claim 1, wherein the first semiconductor layer includes: an outer sidewall that is in contact with the inner spacer; and an inner sidewall that is opposite to the outer sidewall, and
wherein the source/drain region further includes a second semiconductor layer on the inner sidewall of the first semiconductor layer.

11. The integrated circuit device of claim 1, wherein the first semiconductor layer includes fluorine-doped Si, fluorine-doped SiGe, fluorine-doped SiP, fluorine-doped SiGeB, oxygen-doped Si, oxygen-doped SiGe, oxygen-doped SiP, oxygen-doped SiGeB, argon-doped Si, argon-doped SiGe, argon-doped SiP, argon-doped SiGeB, nitrogen-doped Si, nitrogen-doped SiGe, nitrogen-doped SiP, or nitrogen-doped SiGeB, or a combination of two or more thereof.

12. The integrated circuit device of claim 1, wherein the inner spacer includes an oxide of at least one semiconductor material selected from the group consisting of fluorine-doped Si, fluorine-doped SiGe, fluorine-doped SiP, fluorine-doped SiGeB, oxygen-doped Si, oxygen-doped SiGe, oxygen-doped SiP, oxygen-doped SiGeB, argon-doped Si, argon-doped SiGe, argon-doped SiP, and argon-doped SiGeB, or a nitride of at least one semiconductor material selected from the group consisting of nitrogen-doped Si, nitrogen-doped SiGe, nitrogen-doped SiP, and nitrogen-doped SiGeB.

13. An integrated circuit device comprising:
a fin-type active region that protrudes from a substrate and extends in a first horizontal direction;
a plurality of semiconductor patterns on the fin-type active region and overlapping with each other in a vertical direction;
a gate line on the fin-type active region, the gate line surrounding the plurality of semiconductor patterns and extending in a second horizontal direction that intersects the first horizontal direction;
a source/drain region on the fin-type active region, adjacent to the gate line and connected to the plurality of semiconductor patterns; and
an inner spacer between the source/drain region and the gate line,
wherein the source/drain region includes:
a first semiconductor layer having an outer sidewall and an inner sidewall, the outer sidewall in contact with the plurality of semiconductor patterns and the inner spacer, and the inner sidewall opposite to the outer sidewall; and
a second semiconductor layer on the inner sidewall of the first semiconductor layer,
wherein the first semiconductor layer includes a semiconductor material including a first element including at least one selected from the group consisting of fluorine, oxygen, argon, and nitrogen, and
wherein the inner spacer includes an oxide including the first element or a nitride including the first element.

14. The integrated circuit device of claim 13, wherein the inner spacer includes:
a first sidewall that faces the source/drain region; and
a second sidewall that faces the gate line and is opposite to the first sidewall, and
wherein the first sidewall of the inner spacer protrudes from a sidewall of the plurality of semiconductor patterns toward the first semiconductor layer and has a convex profile.

15. The integrated circuit device of claim 14, wherein the first semiconductor layer includes a plurality of grooves, the plurality of grooves being separated from each other in the vertical direction at a location corresponding to the inner spacer,
wherein a portion of the inner spacer vertically overlaps the first semiconductor layer, and
wherein another portion of the inner spacer vertically overlaps the plurality of semiconductor patterns.

16. The integrated circuit device of claim 13, wherein the first semiconductor layer includes a first portion and a second portion, the first portion at a same vertical level as at least a portion of the plurality of semiconductor patterns, and the second portion at a same vertical level as at least a portion of the inner spacer,
wherein the first portion of the first semiconductor layer has a first width in the first horizontal direction, and
wherein the second portion of the first semiconductor layer has a second width that is less than the first width in the first horizontal direction.

17. An integrated circuit device comprising:
a fin-type active region that protrudes from a substrate and extends in a first horizontal direction;
a plurality of semiconductor patterns on the fin-type active region and overlapping with each other in a vertical direction;
a gate line on the fin-type active region, the gate line surrounding the plurality of semiconductor patterns and extending in a second horizontal direction that intersects the first horizontal direction;
a source/drain region on the fin-type active region, the source/drain region adjacent to the gate line and connected to the plurality of semiconductor patterns;
an inner spacer between the source/drain region and the gate line; and
a gate insulating layer between the gate line and the plurality of semiconductor patterns and between the gate line and the inner spacer,
wherein the source/drain region includes:
a buffer layer having an outer sidewall and an inner sidewall, the outer sidewall in contact with the plurality of semiconductor patterns and the inner spacer, and the inner sidewall opposite from the outer sidewall; and
a main semiconductor layer on the inner sidewall of the buffer layer,
wherein the buffer layer includes a semiconductor material including a first element including at least one selected from the group consisting of fluorine, oxygen, argon, and nitrogen, and
wherein the outer sidewall of the buffer layer includes a plurality of grooves, the plurality of grooves separated from each other in the vertical direction at locations corresponding to the inner spacer.

18. The integrated circuit device of claim 17, wherein the inner spacer includes an oxide including the first element or a nitride including the first element.

19. The integrated circuit device of claim 17, wherein a first distance between the main semiconductor layer and a sidewall of the plurality of semiconductor patterns in the first horizontal direction is greater than a second distance between the main semiconductor layer and the inner spacer in the first horizontal direction.

20. The integrated circuit device of claim 17, wherein the inner spacer includes:
a first sidewall that faces the source/drain region; and
a second sidewall that faces the gate line and is opposite to the first sidewall, and
wherein the first sidewall of the inner spacer has a convex profile in contact with the plurality of grooves.
